(19) United States
(12) Patent Application Publication
(10) Pub. No.: US 2019/0242007 A1
(43) Pub. Date: Aug. 8, 2019

(54) SHUTTERS AND METHODS USING THE SAME

(71) Applicant: Essilor International, Charenton-le-Pont Cedex (FR)

(72) Inventors: Johann ROTTE, Charenton-le-Pont (FR); Renaud MERTZ, Charenton-le-Pont (FR); Nicolas TILLIET, Charenton-le-Pont (FR); Pascal DOUTAU, Charenton-le-Pont (FR)

(21) Appl. No.: 16/317,281

(22) PCT Filed: Jul. 13, 2016
(86) PCT No.: PCT/IB2016/001167

§ 371 Date: Jan. 11, 2019

(51) Int. Cl. C23C 14/30

(52) U.S. Cl. CPC C23C 14/30

(57) ABSTRACT

Vapor deposition apparatuses, systems, and methods with a collapsible shutter are described. Embodiments of the present disclosure can be useful for covering evaporator sources within a vacuum chamber yet having a smaller footprint when not in use. Still other embodiments are disclosed.

### CROSS REFERENCE TO RELATED APPLICATIONS

None.

### FIELD OF THE INVENTION

The invention generally concerns devices, systems, and methods related to vacuum deposition of substrates.

### BACKGROUND

Multiple types of functional coatings can be applied to an optical substrate, such as eyeglass lenses. For example, it is not uncommon for a pair of eyeglass lenses to have three to four different coatings, such as an anti-reflective coating (a thin multi-layer coating that reduces light reflecting from the lenses), an anti-scratch coating, an anti-static coating, and a hydrophobic coating.

In the manufacturing of eyeglass lenses, a vapor deposition machine can apply various coatings to a batch of lenses. Within the vapor deposition machine, an evaporator source can disposed in the vacuum chamber below the lens holder and above the floor. A shutter can be selectively interposed between the evaporator source and the lens holder to block the emission from the evaporator source for improved deposition control. A shutter should shield the evaporation source when needed but not interfere with the deposition process at other times.

### SUMMARY

The present disclosure is directed to devices, systems, and methods that facilitate shuttering an evaporation source or target in a vapor deposition machine, where the shutter is collapsible. For example, the shutter can have a smaller footprint when not in use and a larger footprint when needed to shield an evaporator source.

Embodiments include apparatus for vapor deposition onto a substrate that comprise a floor disposed in or defining a portion of a vacuum chamber; a substrate holder disposed in the vacuum chamber above the floor and configured to receive at least one substrate; an evaporator source disposed in the vacuum chamber below the substrate holder and above the floor; and a source shutter. The source shutter comprises at least two blades, the at least two blades configured to move between a first position and a second position such that in the first position, the at least two blades are overlapping along a dimension and the shutter is not covering the evaporator source and in the second position, the at least two blades are overlapping to a lesser extent than in the first position and the shutter is covering the evaporator source. Other embodiments can include method of using the apparatus for coating a substrate, such as a lens.

Other embodiments can include a vacuum deposition method comprising the steps of: moving a source shutter away from an evaporator source disposed in a vacuum deposition chamber, where the source shutter comprises a first blade and a second blade; and evaporating a film forming material from the evaporator source, wherein moving the source shutter away from the evaporator source comprises rotating the first blade thereby causing the second blade to be rotated. The method can further comprise moving the source shutter toward the evaporator source, wherein moving the source shutter toward the evaporator source comprises rotating the first blade thereby causing the second blade to be rotated. The second blade can be rotated by the first blade pushing or pulling the second blade.

Yet other embodiments can include a vacuum deposition method comprising the steps of: moving a source shutter toward an evaporator source disposed in a vacuum deposition chamber, where the source shutter comprises a plurality of blades; and evaporating a film forming material from the evaporator source, wherein moving the source shutter toward the evaporator source comprises moving the plurality of blades such that the plurality of blades are fanned. The deposition method can further comprise moving the source shutter away from the evaporator source, wherein moving the source shutter away from the evaporator source comprises moving the plurality of blades such that the plurality of blades are stacked.

The terms “a” and “an” are defined as one or more unless this disclosure explicitly requires otherwise.

The terms “substantially,” “approximately” and “about” are defined as being largely but not necessarily wholly what is specified (and include wholly what is specified) as understood by one of ordinary skill in the art. In any disclosed embodiment, the term “substantially,” “approximately,” or “about” may be substituted with “within [a percentage] of” what is specified, where the percentage includes 0.1, 1, 5, and 10 percent.

The terms “comprise” (and any form of comprise, such as “comprises” and “comprising”), “have” (and any form of have, such as “has” and “having”), “include” (and any form of include, such as “includes” and “including”) and “contain” (and any form of contain, such as “contains” and “containing”) are open-ended linking verbs. As a result, any of the present devices, systems, and methods that “comprises,” “has,” “includes” or “contains” one or more elements possesses those one or more elements, but is not limited to possessing only those one or more elements. Likewise, an element of a device, system, or method that “comprises,” “has,” “includes” or “contains” one or more features possesses those one or more features, but is not limited to possessing only those one or more features. Additionally, terms such as “first” and “second” are used only to differentiate structures or features, and not to limit the different structures or features to a particular order.

Furthermore, a structure that is capable performing a function or that is configured in a certain way is capable or configured in at least that way, but may also be capable or configured in ways that are not listed.

The feature or features of one embodiment may be applied to other embodiments, even though not described or illustrated, unless expressly prohibited by this disclosure or the nature of the embodiments.

Any of the present devices, systems, and methods can consist of or consist essentially of—rather than comprise/include/contain/have—any of the described elements and/or features and/or steps. Thus, in any of the claims, the term “consisting of” or “consisting essentially of” can be substituted for any of the open-ended linking verbs recited above, in order to change the scope of a given claim from what it would otherwise be using the open-ended linking verb.

Details associated with the embodiments described above and others are presented below.

### BRIEF DESCRIPTION OF THE DRAWINGS

The following drawings illustrate by way of example and not limitation. For the sake of brevity and clarity, every feature of a given structure may not be labeled in every figure in which that structure appears. Identical reference numbers do not necessarily indicate an identical structure. Rather, the same reference number may be used to indicate a similar feature or a feature with similar functionality, as may non-identical reference numbers.

FIG. 1A illustrates a schematic perspective, interior view within a vacuum chamber of an embodiment of a vapor deposition apparatus with a shutter in a first position.

FIG. 1B illustrates a schematic perspective, interior view of the embodiment shown in FIG. 1A with the shutter in a second position.

FIG. 2A illustrates a perspective view of an embodiment of a driving blade.

FIG. 2B illustrates a perspective view of an embodiment of an intermediate blade.

FIG. 2C illustrates a perspective view of an embodiment of lagging blade.

FIG. 3A illustrates a top perspective view of an embodiment of a shutter in a fanned configuration.

FIG. 3B illustrates a bottom perspective view of the shutter embodiment in FIG. 3A in a stacked configuration.

FIG. 3C illustrates a side view of the shutter embodiment in FIG. 3A in a stacked configuration.

FIG. 4 illustrates a close up view of another embodiment of a shutter. This view is a deconstructed view to render the various components visible.

FIG. 5 illustrates a side perspective view of an embodiment of a sleeve.

FIG. 6 illustrates a schematic of a system comprising the embodiment shown in FIG. 1A.

### DETAILED DESCRIPTION

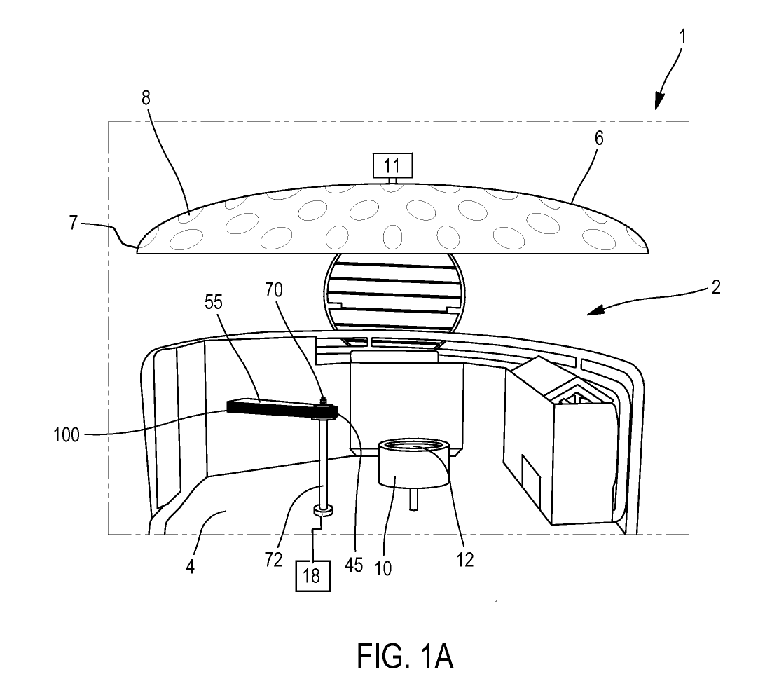

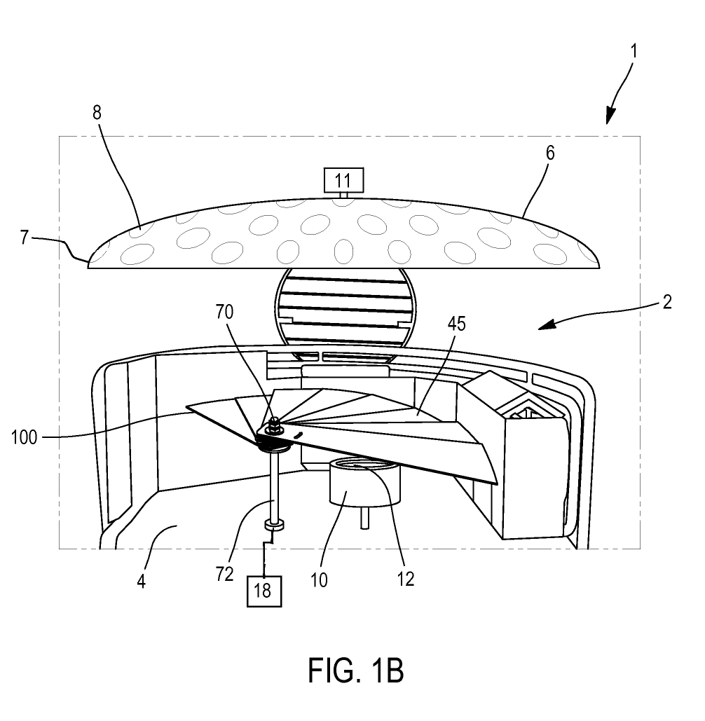

Referring now to FIGS. 1A and 1B, an embodiment of a source shutter 100 disposed in a vapor deposition apparatus 1 is shown. Vapor deposition apparatus 1 can be configured to apply one or more functional layers to the one or more substrates 8. In the embodiments shown, vapor deposition apparatus 1 comprises a vacuum chamber 2 with a substrate holder 6 disposed in chamber 2 opposite a chamber floor 4 and one or more evaporators 10 also disposed in chamber 2 and spaced apart from and below substrate holder 6. Substrate holder 6 comprises a plurality of holders 7 that are each configured to receive and hold a substrate 8. One or more evaporators 10 comprise an evaporation source 12 and are configured to apply one or more functional layers to an exposed surface of one or more substrates 8. In embodiments, substrate holder 6 can be configured to rotate, e.g., via a rotary driver 11 coupled thereto.

Vapor deposition apparatus 1 can also comprise shutter 100 configured to move between a first, refracted position (FIG. 1A) and a second, extended position (FIG. 1B) such that the shutter can selectively shield at least one evaporation source 12. In the extended position, shutter 100 covers evaporation source 12 and physically blocks its vapor path. In the retracted position, shutter 100 is offset from the evaporator source 12 such that it no longer blocks its vapor path.

Source shutter 100 can comprise at least two blades 55 that are configured to move (e.g., rotate) between a first, retracted position and a second, extended position. For example, shutter 100 can comprise 2, 3, 4, 5, 6, 7, 8, 9, 10, 11, 12, 13, 14, 15, or more blades. The number of blades can depend on the size and shape of the blades and the size and shape of the evaporator source. In some embodiments, shutter 100 can comprise 5 to 12 blades. In the first position, one of the blades (e.g., blade 55a) is overlapping a neighboring blade (e.g., blade 55b) to a greater extent than in the second position. When in the second position, blades 55 cooperate to form a shield that is interposed between evaporator source 12 and substrate 8, thereby blocking the evaporated material.

Shutter 100 is configured to collapse when moving to the retracted position thereby having a smaller footprint as compared to the extended position. Stated another way, shutter 100 can comprise an exposed surface area in the first position that is less than an outer, exposed surface area in the second position. Exposed surface area can be the total surface area of each blade that is not overlapped by another blade. In embodiments, the exposed surface area increases at least 2-fold, 3-fold, 4-fold, 5-fold, or more from the first position to the second position.

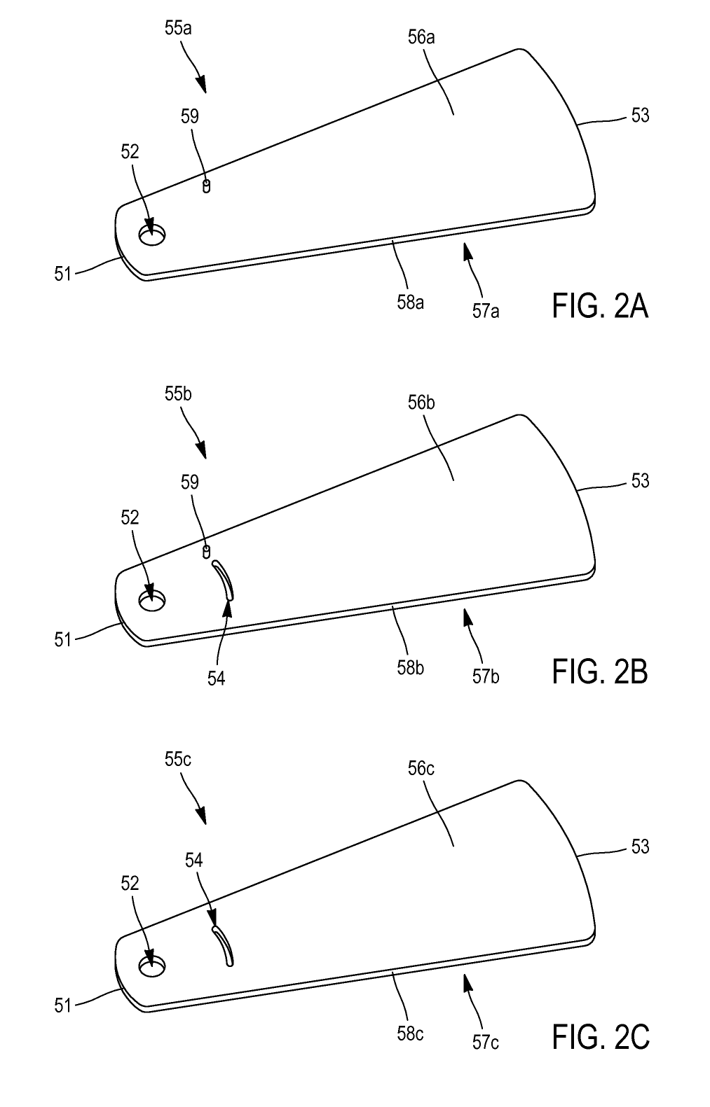

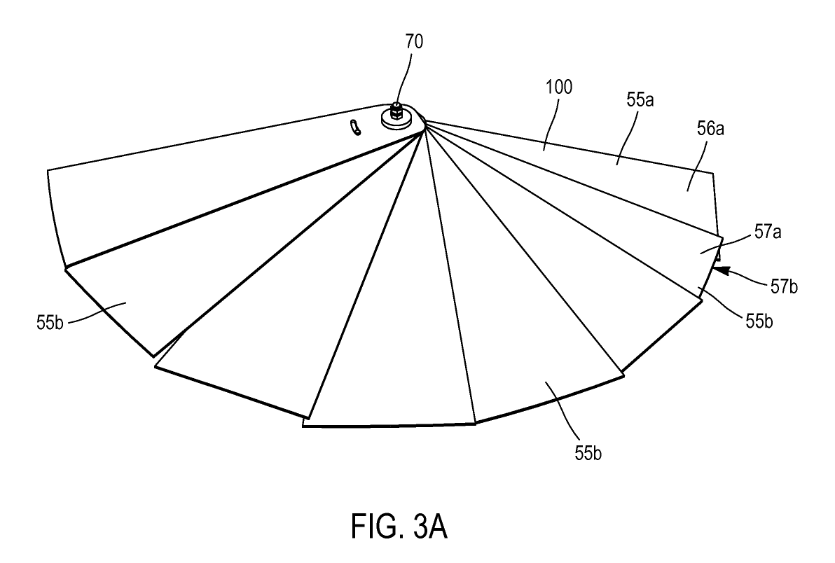

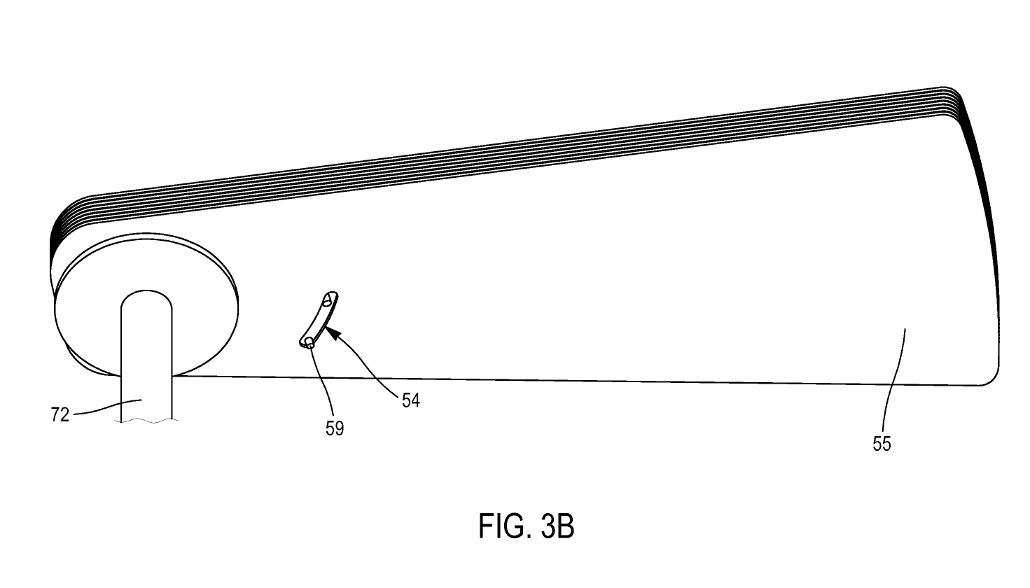

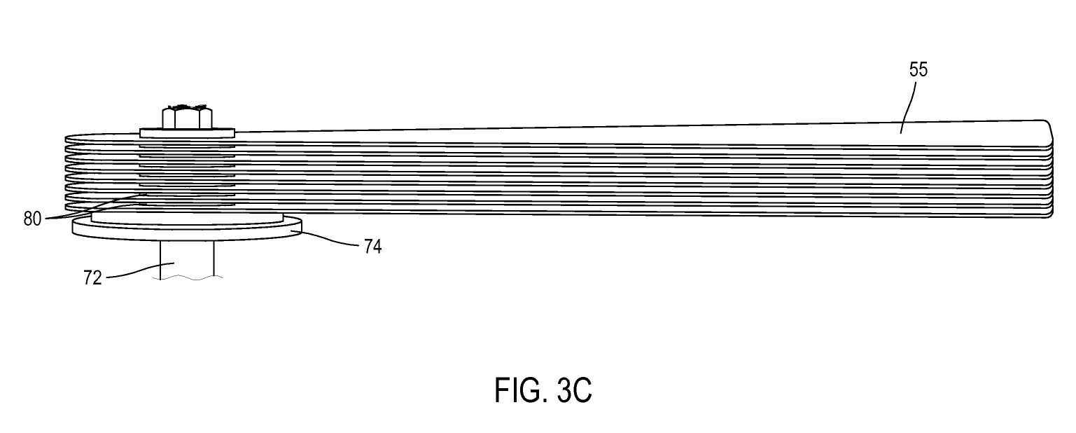

With reference to FIGS. 2A to 2C and 3A to 3C, each blade (e.g., 55a, 55b, 55c, collectively referred to as blade 55) can be a thin structure, e.g., a sheet of material. For example, each blade 55 can have an upper surface 56 and a lower surface 57 and a perimeter surface 58 extending between the upper and lower surfaces, and upper surface 56 and lower surface 57 can have a greater surface area than perimeter surface 58. Upper surface 56 and lower surface 57 can be flat and have substantially the same surface area. For neighboring blades, like blades 55a and 55b, a upper surface 56a of blade 55a overlaps a lower surface 57b of blade 55b, and overlaps to a greater extent when in the first position (FIG. 1A) as compared with the second position (FIG. 1B).

Each blade 55 can be a stiff structure. In some embodiments, each blade 55 can have sufficient stiffness such that it can support its own weight when it extends horizontally and is only supported at one end. In embodiments, blade 55 can comprise one or more metals, metal nitrides, metal oxides, or combinations thereof. Blade 55 can comprise one or more materials selected from molybdenum, tantalum, tungsten, titanium, boron nitride, gold, silver, platinum, copper, aluminum, nickel, beryllium, silicon carbide, silicon nitride, boron nitride, silicon oxide, beryllium oxide, and aluminum nitride. In embodiments, blade can have a thickness between 0.1 mm to 3 mm; the thickness can be about or at least e.g., 0.2, 0.3, 0.4, 0.5, 0.6., 0.7, 0.8, 0.9, 1, 1.1, 1.2, 1.3, 1.4, 1.5, 1.6, 1.7, 1.8, 1.9, 2, 2.2, 2.4, 2.6, or 2.8 mm.

In the embodiment shown, blade 55 can comprise a base 51 and a distal end 53 opposite the base. Base 51 of each blade 55 can be configured to couple to a rotatable shaft 70. For example, base 51 can define an aperture 52 which is sized and shaped such that shaft 70 can extend through the aperture. Shaft 70 (FIGS. 1A and 1B) extends upright relative to floor 4. Shaft 70 can extend through each aperture 52 of each blade 55, such that the blades extend horizontally and bases 51 are stacked upon each other. One or more blades 55 can be configured to rotate about shaft 70, but at least one blade 55 (e.g., blade 55c, referred to as the driving blade) is coupled in fixed relation to shaft 70. Rotatable shaft 70 can be configured to rotate such blade to which it is coupled between the first position (FIG. 1A) and the second position (FIG. 1B).

At least one of the blades (e.g., blade 55a and 55b) can be configured to pull a neighboring blade (e.g., blade 55b) from the first position to the second position. For example, with reference to FIG. 2, blade 55b defines a slot 54 and neighboring blade 55a is coupled to a pin 59 configured to extend through the slot. Slot 54 and pin 59 are configured such that blade 55b with the pin pulls blade 55a with the slot when moving between the first position and the second position. Driving blade 55a can only comprise pin 59 that extends into slot 54 of neighboring blade 55. The blade (e.g., lagging blade 55c) that is still driven by driving blade 55a yet is the furthest blade from the driving blade need only comprise slot 54 through which pin 59 of neighboring blade 55b can extend. Blades 55b that are sandwiched between blade 55a and blade 55c will have both pin 59 and slot 54.

In embodiments, slot 54 is sized and shaped such that pin 59 extending therethrough can move along an arced path as the blade to which the pin (e.g., blades 55a or 55b) is coupled rotates about shaft 70. For example, slot 54 can define a curve along its length where the radius of curvature is approximately the distance from the slot to shaft 70. The length of slot 54 can correspond to the degrees of separation between neighboring blades (e.g., blades 55a, 55b or blades 55b and 55c) when the blades are in the second position (e.g., having a fanned configuration).

Pin 59 coupled to blade 55 can extend from upper surface 56 or lower surface 57, which surface dictated by the location within blade assembly 45 of driving blade 55a. Pin 59 can be configured to extend into slot 54 of a neighboring blade 55. Pin 59 can have a length that does not exceed the thickness of blade 55 plus the distance between two blades (e.g., blades 55a, 55b) or the thickness of O-ring 80. Each pin 59 of each blade 55 that has a pin can extend from the same surface as the other blades of blade assembly 45, whether it be from upper surface 56 or lower surface 57.

Source shutter 100 can be configured such that over-rotation of any one of the blades 55 is prevented or minimized during actuation from the first position to the second position. For example, one of the outermost blades (e.g., blade 55c) can be coupled in fixed relation to a wall defining chamber 2 or a fixed component within chamber e.g., configured not to rotate when shaft 70 rotates.

To reduce the friction between neighboring blades 55 when rotating between the first position and the second position, shutter 100 can further comprise an O-ring 80 (FIG. C) disposed around shaft 70 and between each set of neighboring blades 55. O-ring 80 can comprise a self-lubricating polymer, e.g., polytetrafluoroethylene, nylon, acetal (e.g., Delrin®), ultrahigh-molecular weight polyethylene, and/or a phenolic plastic.

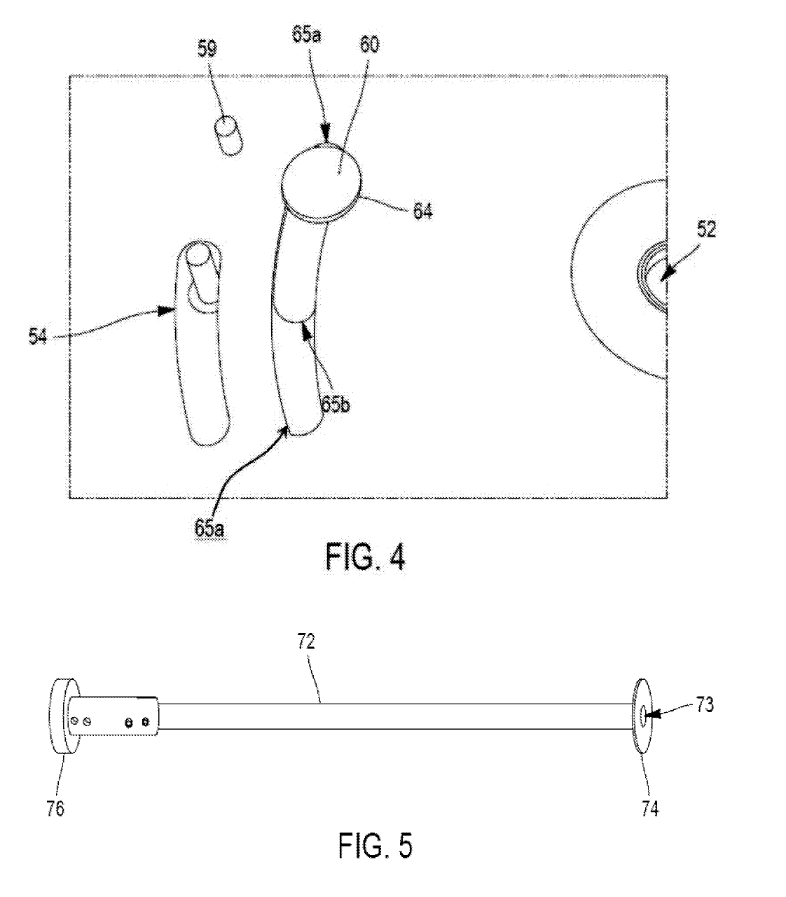

With reference to FIG. 4, another embodiment of shutter 100 can be the same as that shown and described in FIGS. 3A to 3C except that it can further comprise a rivet 60 extending from at least one of blades 55 and two or more slots 65a, 65b defined by adjacent blades to receive the rivet. The rivet 60 and slots (e.g., 65a, 65b) can be configured to prevent the blades 55 through which the rivet extends from unwanted vertical separation. Rivet 60 for example, can prevent pin 59 from coming out of slot 54, particularly if pin 59 is not riveted. Rivet 60 comprises a pin (not visible from this view) coupled to blade 55 at one end and a wide head 64 at the other. The pin of rivet 60 extends through two or more slots 65a, 65b of two or more adjacent blades 55. Slots 65a, 65b are each sized and shaped such that rivet 60 extending therethrough can move along an arced path as blade 55 to which the rivet is coupled rotates about shaft 70. For example, slots 65a, 65b can define a curve along its length where the radius of curvature is approximately the distance from the slots to shaft 70.

In the embodiment shown, shaft 70 extends through sleeve 72. Sleeve 72 can be configured to provide some upright support to shaft 70. For example, with reference to FIG. 5, sleeve 72 can define a conduit 73 configured such that shaft 70 can freely rotate within the conduit. Sleeve 72 can also be configured to provide a platform for blades 55. For example, coupled to the distal end of sleeve 72 is a horizontally-extending support member 74. Shaft 70 extends beyond support member 74, and blades 55 coupled to the shaft are supported by the support member 74. Sleeve 72 can be coupled to a flanged member 76 at the proximal end to couple the sleeve to floor 4.

Returning to FIGS. 1A and 1B, shaft 70 can be coupled to an actuator 18. Actuator 18 can be a pneumatic, hydraulic, electric, or manual type actuator. For example, shaft 70 can be coupled to a double-acting pneumatic cylinder.

In various embodiments, an evaporator 10 can be configured to have an evaporator source 12 that is an ion source (e.g., an RF high frequency ion source) or a vapor deposition source. For example, evaporator 10 can be configured for electron beam evaporation, joule effect evaporation, ion-assisted evaporation, ion beam sputtering, chemical vapor deposition, physical vapor deposition, atomic vapor deposition, or resistive evaporation. Evaporator source 12 can have a source area (i.e., the area needed to be shuttered) of at least 2 cm², cm², 4 cm², 5 cm², 6 cm², cm², 8 cm², 9 cm², 10 cm², or more.

In embodiments, evaporator 10 can be configured to deposit one or more functional layers on substrate 8. Substrate 8 can be any article to which thin film coating(s) is desired. In the embodiment shown, substrate 8 is an optical lens. However, a substrate can also be a thin film device, a film, or an ophthalmic lens. Functional layers applied to substrate 8 can include: an anti-reflective layer, a high refractive index layer, a low refractive index layer, an anti-static layer, a hydrophilic layer (e.g., an anti-fog layer), a hydrophobic layer, an anti-scratch layer, a high reflectance layer (e.g., a mirror layer), a tinted/colored layer, an adhesive layer for facilitating adhesion to substrate 8 or between the layer, a pad control layer, a gradient layer, a light manipulating layer, and/or a hardening layer.

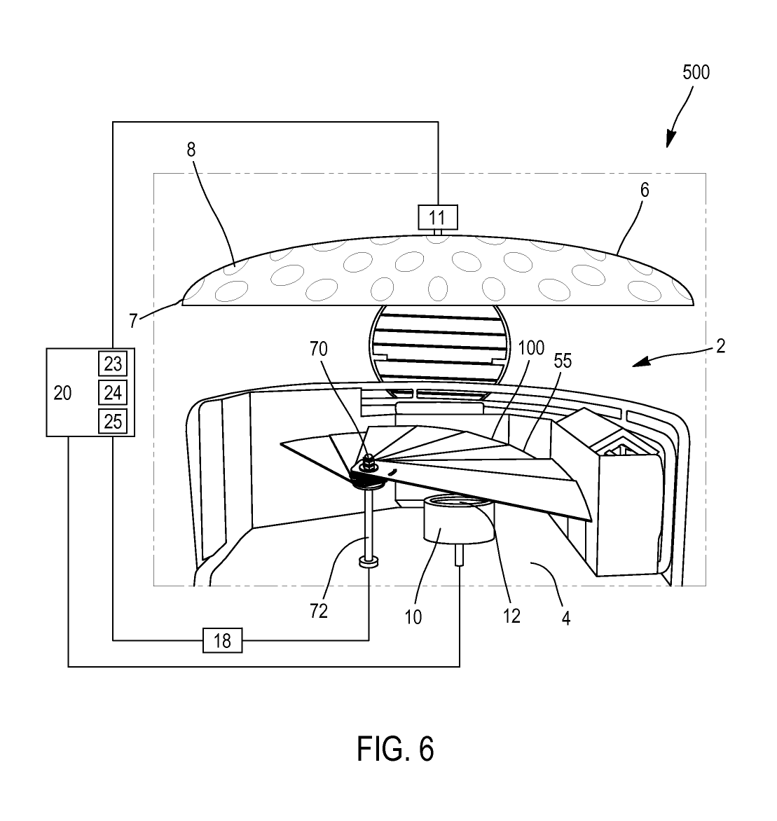

In order to control actuator 18, in some embodiments, a controller is in communication with one or more actuators and configured to actuate the one or more actuators. In some embodiments, the controller is a system controller 20. For example, with reference to FIG. 6, system 500 comprises apparatus 1 with shutter 100 as described above and a system controller 20 provided with a data-processing system comprising a microprocessor 23 configured to transmit instructions to apparatus 1 for actuating actuator 18 to cover or uncover evaporation source 12. The system 500 can further be equipped with a memory 24, especially a non-volatile memory, allowing it to load and store a software program, that, when executed in the microprocessor 23, allows the substrate-coating process to be implemented by apparatus 1. This non-volatile memory 24 can be, for example, a ROM (read-only memory). Furthermore, the system controller 20 comprises a memory 25, especially a volatile memory, allowing data to be stored during the execution of the software package. This volatile memory 25 may be, for example, a RAM or EEPROM (“random access memory” or “electrically erasable programmable read-only memory”, respectively).

In some embodiments, the system controller 20 can be configured to execute a substrate coating process. Moreover, the system controller 20 can be in communication with the one or more evaporators and the one or more shutters 100. The coating process to be executed can comprise actuating shutter 100 to cover evaporation source 12 (e.g., by rotating blades to the second position) and igniting evaporator 10. The coating process can also comprise actuating rotary driver 11 to rotate substrate holder 6. Once evaporation source 12 has reached a desired output level, shutter 100 can be actuated to uncover evaporation source 12, e.g., by rotating blades to the first position. Once evaporator 10 has operated to a defined time, shutter 100 can be actuated to cover evaporator source 12 and evaporator 10 can be turned off.

Other embodiments can comprise a method of moving source shutter 100 away from evaporator source 12 and evaporating a film forming material from the evaporator source. In such embodiments, source shutter 100 can comprise a first blade 55a and a second blade 55b. Source shutter 100 can be moved away from evaporator source 12 by rotating the first blade thereby causing the second blade to be rotated. The method can also comprise moving source shutter 100 toward evaporator source 12 by rotating the first blade 55a and thereby causing the second blade 55b to be rotated but in the opposite direction. For example, second blade 55b can be rotated by first blade 55a pushing the second blade in one direction or pulling the second blade in the opposite direction.

Another embodiment can comprise moving source shutter 100 toward evaporator source 12 disposed in vacuum deposition apparatus 1 and evaporating a film forming material from the evaporator source. Source shutter can comprise a plurality of blades 55. Source shutter 100 can move toward the evaporator source by moving the plurality of blades such that the blades are fanned. The method can also comprise moving source shutter 100 away from evaporator source 12 by moving blades 55 such that blades 55 are stacked.

The above specification provides a complete description of the structure and use of exemplary embodiments. Although certain embodiments have been described above with a certain degree of particularity, or with reference to one or more individual embodiments, those skilled in the art could make numerous alterations to the disclosed embodiments without departing from the scope of this invention. As such, the illustrative embodiments of the present vapor deposition apparatuses and methods are not intended to be limiting. Rather, the present devices, systems, and methods include all modifications and alternatives falling within the scope of the claims, and embodiments other than those shown may include some or all of the features of the depicted embodiments. For example, components may be combined as a unitary structure and/or connections may be substituted. Further, where appropriate, aspects of any of the examples described above may be combined with aspects of any of the other examples described to form further examples having comparable or different properties and addressing the same or different problems. Similarly, it will be understood that the benefits and advantages described above may relate to one embodiment or may relate to several embodiments.

The claims are not to be interpreted as including means-plus- or step-plus-function limitations, unless such a limitation is explicitly recited in a given claim using the phrase(s) “means for” or “step for,” respectively.

1. An apparatus for vapor deposition onto a substrate, the apparatus comprising:
a floor disposed in or defining a portion of a vacuum chamber;
a substrate holder disposed in the vacuum chamber above the floor and configured to receive at least one substrate;
an evaporator source disposed in the vacuum chamber below the substrate holder and above the floor; and
a source shutter comprising at least two blades, the at least two blades configured to move between a first position and a second position such that in the first position, the at least two blades are overlapping along a dimension and the shutter is not covering the evaporator source and in the second position, the at least two blades are overlapping to a lesser extent than in the first position and the shutter is covering the evaporator source.

2. The apparatus of claim 1, wherein at least one of the at least two blades is configured to pull another blade from the first position to the second position.

3. The apparatus claim 1, wherein at least one of the at least two blades comprises a slot and another blade is coupled to a pin configured to extend through the slot, the combination of the slot and pin configured such that the blade with the pin pulls the blade with the slot when moving between the first position and the second position.

4. The apparatus of claim 1, comprising a rotatable shaft coupled in fixed relation to at least one of the at least two blades and configured to rotate the at least one blade to which it is coupled between the first position and the second position.

5. The apparatus of claim 4, wherein another of the at least two blades is coupled in fixed relation to a non-rotating component within or defining the vacuum chamber.

6. The apparatus of claim 1, wherein the blades are configured to rotate between the first position and the second position.

7. The apparatus of claim 1, further comprising an O-ring disposed between two blades, the O-ring comprising a self-lubricating polymer.

8. The apparatus of claim 1, wherein the shutter comprises an outer, exposed surface area in the first position that is greater than an outer, exposed surface area in the second position.

9. The apparatus of claim 8, wherein the outer surface area increases at least 2-fold or wherein the shutter comprises at least 3 blades.

10. The apparatus of claim 1, wherein:
the evaporator source is an ion source or a vapor deposition source;
the evaporator source is an electron beam evaporator source or joule effect evaporator source;
the evaporator source is a RF high frequency ion source;
the evaporator source has a source area of at least 5 cm²;
the blade comprises one or more of molybdenum, tantalum, tungsten, titanium, boron nitride, gold, silver, platinum, copper, aluminum, nickel, beryllium, silicon carbide, silicon nitride, boron nitride, silicon oxide, beryllium oxide, and aluminum nitride;
the at least two blades are coupled to a double-acting pneumatic cylinder comprising a piston rod such that movement of the piston rod causes rotation of the at least two blades;
the blades are fanned in the second position; or
the blades are stacked in the first position.

11. A vacuum deposition method comprising the steps of:
moving a source shutter away from an evaporator source disposed in a vacuum deposition chamber, where the source shutter comprises a first blade and a second blade; and
evaporating a film forming material from the evaporator source,
wherein moving the source shutter away from the evaporator source comprises rotating the first blade thereby causing the second blade to be rotated.

12. The method of claim 11, further comprising moving the source shutter toward the evaporator source, wherein moving the source shutter toward the evaporator source comprises rotating the first blade thereby causing the second blade to be rotated.

13. The method of claim 11, wherein the second blade is rotated by the first blade pushing or pulling the second blade.

14. A vacuum deposition method comprising the steps of:
moving a source shutter toward an evaporator source disposed in a vacuum deposition chamber, where the source shutter comprises a plurality of blades; and
evaporating a film forming material from the evaporator source,
wherein moving the source shutter toward the evaporator source comprises moving the plurality of blades such that the plurality of blades are fanned.

15. The vacuum deposition method of claim 14, further comprising moving the source shutter away from the evaporator source, wherein moving the source shutter away from the evaporator source comprises moving the plurality of blades such that the plurality of blades are stacked.
